(19) United States
(12) Patent Application Publication
(10) Pub. No.: US 2012/0103407 A1
(43) Pub. Date: May 3, 2012

(54) SOLAR CELL AND METHOD FOR MANUFACTURING THE SOLAR CELL

(76) Inventors: Nam-Kyu SONG, Hwaseong-si (KR); Min-Seok OH, Yongin-si (KR); Min PARK, Seoul (KR); Yeon-Ik JANG, Seoul (KR); Hoon Ha JEON, Gwangju-si (KR); Yun-Seok LEE, Seoul (KR); Cho-Young LEE, Suwon-si (KR)

(21) Appl. No.: 13/079,328

(22) Filed: Apr. 4, 2011

(30) Foreign Application Priority Data
Oct. 28, 2010 (KR) 10-2010-0106265

(51) Int. Cl. H01L 31/0224; H01L 31/18; H01L 31/0216

(52) U.S. Cl. 136/256; 438/57; 257/E31.126

(57) ABSTRACT

An exemplary embodiment of the present invention provides a method for manufacturing a solar cell, which includes: forming a first semiconductor layer on a first surface of a light-absorbing layer, forming a second semiconductor layer on a second surface of the light-absorbing layer, forming a first transparent conductive layer having one X-ray diffraction peak on the first semiconductor layer in a first direction, forming a second transparent conductive layer having one X-ray diffraction peak on the second semiconductor layer in a second direction opposite to the first direction, forming a first electrode on the first transparent conductive layer in the first direction and forming a second electrode on the second transparent conductive layer in the second direction, in which at least one of the first transparent conductive layer and the second transparent conductive layer is formed at about 180 to about 220° C., at least one of the first transparent conductive layer and the second transparent conductive layer includes oxidized tungsten, and 2θ is 30.2±0.1 degrees in the X-ray diffraction peak.

### CROSS-REFERENCE TO RELATED APPLICATION

This application claims priority to and the benefit of Korean Patent Application No. 10-2010-0106265 filed on Oct. 28, 2010, the entire disclosure of which is hereby incorporated by reference herein in it's entirety .

### BACKGROUND OF THE INVENTION

(a) Technical Field

The present disclosure relates to a solar cell and a method for manufacturing the solar cell. (b) Description of the Related Art

Solar cells convert solar energy into electrical energy. The solar cells are diodes basically formed by PN junction and classified into various types in accordance with the materials used for a light-absorbing layer.

The solar cells using silicon for the light-absorbing layer falls into a crystalline wafer type of solar cell and a thin film type (crystalline, amorphous) of solar cell.

The crystalline wafer type of solar cell has an excellent junction characteristic of the P-layer and the N-layer, such that the output current and the fill factor are increased.

The thin film type of solar cell uses a glass substrate as the material, such that the manufacturing cost is relatively low.

Further, hetero junction solar cells are under development. The hetero junction solar cells have thin amorphous silicon disposed on both sides of a crystalline substrate and use a transparent conductive layer for an anti-reflective layer on the amorphous silicon.

The above information disclosed in this Background section is only for enhancement of understanding of the background of the invention and therefore it may contain information that does not form the prior art that is already known in this country to a person of ordinary skill in the art.

### SUMMARY OF THE INVENTION

Exemplary embodiments of the present invention have been made in an effort to provide a solar cell having the benefits of having increased efficiency by forming a transparent conductive layer that can reduce absorptance of incident light.

An exemplary embodiment of the present invention provides a method for manufacturing a solar cell, which includes: forming a first semiconductor layer on a first surface of a light-absorbing layer, forming a second semiconductor layer on a second surface of the light-absorbing layer; forming a first transparent conductive layer having one X-ray diffraction peak on the first semiconductor layer in a first direction, forming a second transparent conductive layer having one X-ray diffraction peak on the second semiconductor layer in a second direction opposite to the first direction, forming a first electrode on the first transparent conductive layer in the first direction and forming a second electrode on the second transparent conductive layer in the second direction, in which at least one of the first transparent conductive layer and the second transparent conductive layer is formed at about 180 to about 220° C., at least one of the first transparent conductive layer and the second transparent conductive layer includes oxidized tungsten, and 2θ is 30.2±0.1 degrees in the X-ray diffraction peak. The forming the first transparent conductive layer or the second transparent conductive layer may further include injecting argon gas and oxygen gas, wherein the pressure ratio of the argon gas and the oxygen gas may be in a range of about 8:1 to about 11:1.

At least one of the first transparent conductive layer and the second transparent conductive layer may further include oxidized indium.

The weight ratio of the oxidized indium and the oxidized tungsten in at least one of the first transparent conductive layer and the second transparent conductive layer may be about 99:1.

At least one of the first transparent conductive layer and the second transparent conductive layer may further include at least one of Sn, Mo, Ti, Zr, Zn, Gd, Nb, Nd and Ta.

The first transparent conductive layer and the second transparent conductive layer may be simultaneously formed.

Sheet resistance of at least one of the first transparent conductive layer and the second transparent conductive layer may be in a range of about 26.1 to about 26.4Ω.

The light-absorbing layer may be made of crystalline silicon.

The first semiconductor layer may be formed by doping amorphous silicon with P-type impurities.

The second semiconductor layer may be formed by doping amorphous silicon with N-type impurities.

Another exemplary embodiment of the present invention provides a solar cell including: a first semiconductor layer disposed on a first surface of a light-absorbing layer, a second semiconductor layer disposed on a second surface of the light-absorbing layer, a first transparent conductive layer disposed on the first semiconductor layer in a first direction, a second transparent conductive layer disposed on the second semiconductor layer in a second direction opposite to the first direction, a first electrode disposed on the first transparent conductive layer in the first direction and a second electrode disposed on the second transparent conductive layer in the second direction, in which at least one of the first transparent conductive layer and the second transparent conductive layer includes oxidized tungsten, and at least one of the first transparent conductive layer and the second transparent conductive layer has one X-ray diffraction peak, and 2θ is 30.2±0.1 degrees in the X-ray diffraction peak.

Another exemplary embodiment of the present invention provides a solar cell including: a first buffer layer formed of amorphous silicon and disposed on a first surface of a light-absorbing layer, in which the light-absorbing layer is made of crystalline silicon, a second buffer layer formed of amorphous silicon and disposed on a second surface of the light-absorbing layer, a first semiconductor layer formed of amorphous silicon doped with P-type impurities and disposed on the first buffer layer in a first direction, a second semiconductor layer formed of amorphous silicon doped with N-type impurities and disposed on the second buffer layer in a second direction opposite to the first direction, a first transparent conductive layer disposed on the first semiconductor layer in the first direction, a second transparent conductive layer disposed on the second semiconductor layer in the second direction, a first electrode formed of a low resistance metal and disposed on the first transparent conductive layer in the first direction and a second electrode formed of a low resistance metal and disposed on the second transparent conductive layer in the second direction. Each of the first transparent conductive layer and the second transparent conductive layer includes oxidized tungsten and oxidized indium in a weight ratio of the oxidized indium and the ozidized tungsten of about 99:1, and each of the first transparent conductive layer and the second transparent conductive layer has one X-ray diffraction peak, and 2θ is 30.2±0.1 degrees in the X-ray diffraction peaks of the first transparent conductive layer and the second transparent conductive layer.

According to exemplary embodiments of the present invention, by forming transparent conductive layers at about 180 to about 220° C. such that the transparent conductive layers each have one X-ray diffraction peak in which θ is 30.2±0.1 degrees, the light absorptance of the transparent conductive layers may be reduced which in turn may thereby increase the efficiency of a solar cell.

### BRIEF DESCRIPTION OF THE DRAWINGS

FIG. 1 is a cross-sectional view of a solar cell according to an exemplary embodiment of the present invention.

FIGS. 2 to 5 are views sequentially showing a method of manufacturing other solar cell according to an exemplary embodiment of the present invention.

FIG. 6 is a graph comparing X-ray diffraction peaks of transparent conductive layers according to an exemplary embodiment and a comparative example.

FIG. 7 is a table comparing sheet resistance of the transparent conductive layers of an exemplary embodiment and the comparative example.

FIG. 8 is a graph comparing light transmittance of the transparent conductive layers of an exemplary embodiment and the comparative example.

FIG. 9 is a graph comparing light absorptance of the transparent conductive layer of an exemplary embodiment and the comparative example.

FIG. 10 is a graph comparing characteristics of solar cells according to an exemplary embodiment and the comparative example.

### DETAILED DESCRIPTION OF EXEMPLARY EMBODIMENTS

Exemplary embodiments of the present invention will be described more fully hereinafter with reference to the accompanying drawings. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

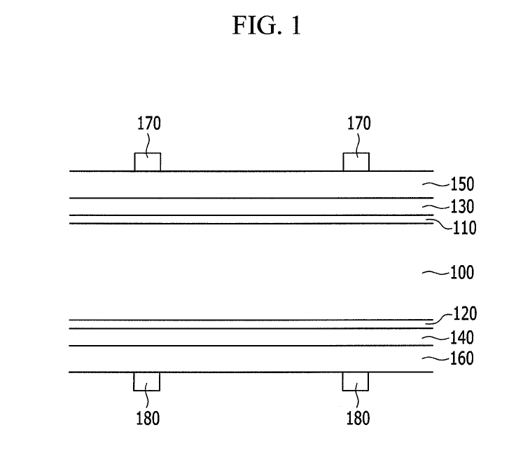

FIG. 1 is a cross-sectional view of a solar cell according to an exemplary embodiment of the present invention.

As shown in FIG. 1, a solar cell according to an exemplary embodiment of the present invention includes a light-absorbing layer 100, a first buffer layer 110, a first semiconductor layer 130, a first transparent conductive layer 150, and a first electrode 170, which are sequentially disposed on a first surface of the light-absorbing layer 100, and a second buffer layer 120, a second semiconductor layer 140, a second transparent conductive layer 160, and second electrodes 180, which are sequentially disposed on a second surface of the light-absorbing layer 100.

A crystalline silicon substrate is used for the light-absorbing layer 100, which functions as an N-type semiconductor that substantially absorbs light.

The first semiconductor layer 130 is formed by doping amorphous silicon with P-type impurities, such as, for example, boron (B) and aluminum (Al).

Solar light absorbed by PN junction of the light-absorbing layer 100 and the first semiconductor layer 130 generates current.

The first buffer 110 is disposed between the light-absorbing layer 100 and the first semiconductor layer 130 and is made of amorphous silicon. A defect is caused in the junction of the light-absorbing layer 100 and the first semiconductor layer 130, but the first buffer layer 110 prevents the defect.

The second semiconductor layer 140 is formed by doping amorphous silicon with N-type impurities, such as, for example, phosphorous (P). The second semiconductor layer 140 prevents electron recombination.

The second buffer layer 120 is disposed between the light-absorbing layer 100 and the second semiconductor layer 140 and is made of amorphous silicon. A defect is caused in the junction of the light-absorbing layer 100 and the second semiconductor layer 140, but the second buffer layer 120 prevents the defect.

Light is received through the surface of the first transparent conductive layer 150. The first transparent conductive layer 150 is made of oxidized indium (In₂O₃) and oxidized tungsten (WO₃) and the weight ratio of the oxidized indium and the oxidized tungsten is about 99:1. The first transparent conductive layer 150 has one X-ray diffraction peak and 2θ is 30.2 ±0.1 degrees in the X-ray diffraction peak. The first transparent conductive layer 150 can reduce incident light absorptance.

Further, the first transparent conductive layer 150 functions as an anti-reflective layer that prevents the incident light from reflecting and allows current to smoothly flow from the first semiconductor layer 130 to the first electrode 170.

The second transparent conductive layer 160 is made of oxidized indium (In₂O₃) and oxidized tungsten (WO₃) and the weight ratio of the oxidized indium and the oxidized tungsten is about 99:1. The second transparent conductive layer 160 has one X-ray diffraction peak and 2θ is 30.2±0.1 degrees in the X-ray diffraction peak.

The second transparent conductive layer 160 prevents electron recombination and allows current to smoothly flow from the second semiconductor layer 140 to the second electrode 180.

The first electrode 170 and the second electrode 180 may be made of a low-resistance metal such as, for example, silver (Ag) and designed in a grid pattern, such that it is possible to reduce shadowing loss and sheet resistance.

As described above, the first transparent conductive layer 150 receiving light includes oxidized indium (In₂O₃) and oxidized tungsten (WO₃) and has one X-ray peak where 2θ is 30.2±0.1 degrees, such that it is possible to increase the efficiency of the solar cell by reducing absorptance of incident light.

Next, a method for manufacturing a solar cell according to an exemplary embodiment of the present invention is described in detail with reference to FIGS. 2 to 5 and FIG. 1.

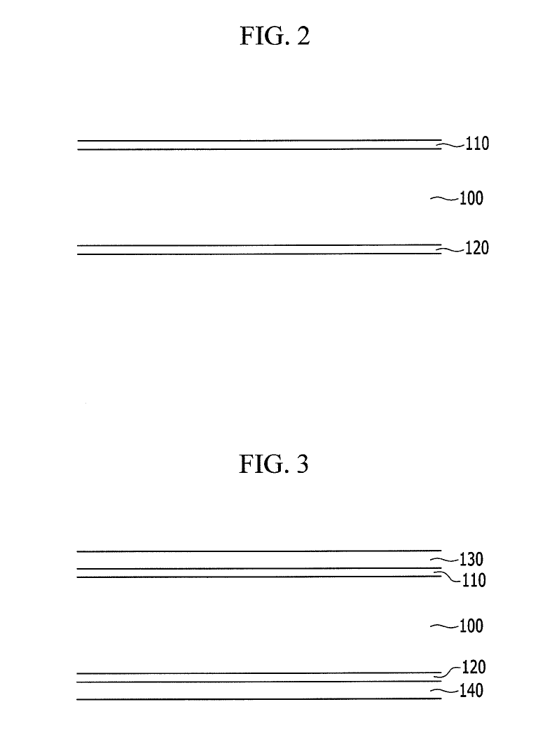

FIGS. 2 to 5 are views sequentially showing a method of manufacturing a solar cell according to an exemplary embodiment of the present invention.

As shown in FIG. 2, the first buffer layer 110 and the second buffer layer 120 are formed on the first surface and the second surface of the light-absorbing layer 100, respectively. The light-absorbing layer 100 uses a crystalline silicon substrate, and the first buffer layer 110 and the second buffer layer 120 are made of amorphous silicon.

Next, as shown in FIG. 3, the first semiconductor layer 130 is formed on the first buffer layer 110, in a first direction, and the second semiconductor layer 140 is formed on the second buffer layer 120, in a second direction opposite to the first direction.

The first semiconductor layer 130 is formed by doping amorphous silicon with P-type impurities, such as, for example boron (B) and aluminum(Al), while the second semiconductor layer 140 is formed by doping amorphous silicon with N-type impurities, such as, for example, phosphorous (P).

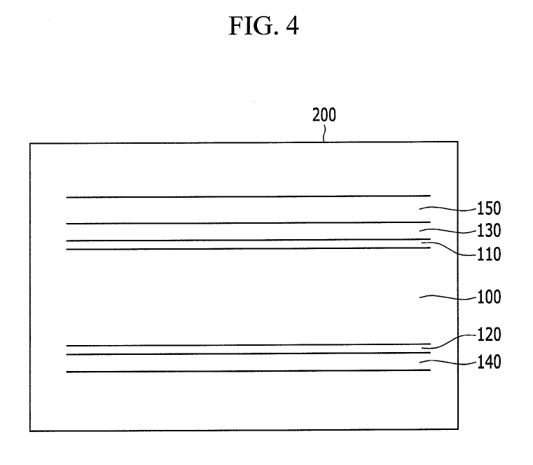

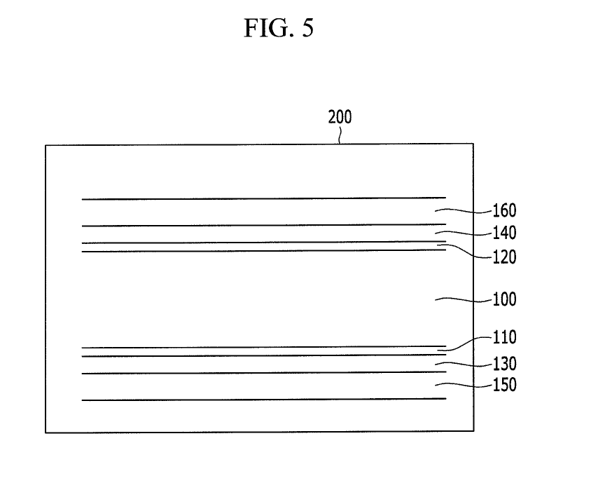

Next, as shown in FIG. 4 and FIG. 5, the first transparent conductive layer 150 is formed on the first semiconductor layer 130 in a process chamber 200 and then the process chamber is turned upside down and the second transparent conductive layer 160 is formed on the second semiconductor layer 140. Further, the first transparent conductive layer 150 and the second transparent conductive layer 160 may be simultaneously formed.

The first transparent conductive layer 150 and the second transparent conductive layer 160 are made of oxidized indium and oxidized tungsten and it is preferable that the weight ratio of the oxidized indium and the oxidized tungsten is about 99:1.

The first transparent conductive layer 150 and the second transparent conductive layer 160 are formed by ion plating and deposited at about 180 to about 220° C. temperature of the light-absorbing layer 100. In this process, argon gas (Ar) at about 0.226 to about 0.256 Pa and oxygen gas (O₂) at about 0.02 to about 0.03 Pa are injected and discharged in the process chamber 200. That is, the pressure ratio of the argon gas and the oxygen gas in the process chamber 200 is about 8:1 to about 11:1.

Further, the first transparent conductive layer 150 and the second transparent conductive layer 160 may be formed by, for example, sputtering, deposition, spray pyrolysis, and pulsed laser ablation.

The first transparent conductive layer 150 and the second transparent conductive layer 160 formed as described above have one X-ray diffraction peak, respectively, and 2θ is 30.2±0.1 degrees in the X-ray diffraction peak.

Thereafter, as shown in FIG. 1, the first electrode 170 is formed on the first transparent conductive layer 150 in the first direction and the second electrode 180 is formed on the second transparent conductive layer 160 in the second direction. The first electrode 170 and the second electrode 180 may be made of low-resistance metal, such as, for example, silver (Ag) and designed in a grid pattern, such that it is possible to reduce shadowing loss and sheet resistance.

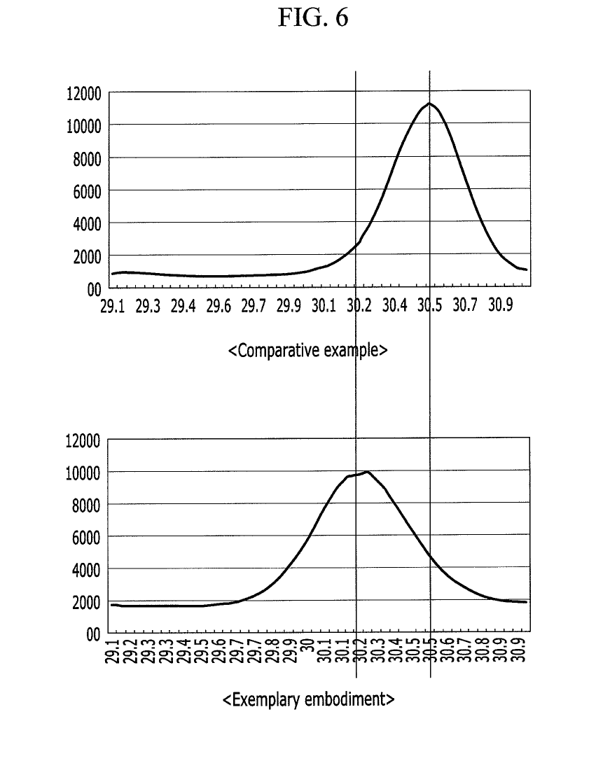

Hereinafter, the result of comparing various characteristics of a solar cell according to an exemplary embodiment of the present invention with a comparative example is described in detail with reference to FIG. 6 to FIG. 10.

The comparative example is a solar cell with a transparent conductive layer deposited at room temperature, while in an exemplary embodiment of the present invention, a solar cell with a transparent conductive layer is deposited at about 200° C.

FIG. 6 is a graph comparing X-ray diffraction peaks of the transparent conductive layers of an exemplary embodiment and the comparative example.

It was shown that the transparent conductive layer of the solar cell according to the comparative example had one X-ray diffraction peak and 2θ was 30.5±0.1 degrees in the X-ray diffraction peak.

It was shown that the transparent conductive layer of the solar cell according to an exemplary example had one X-ray diffraction peak and 2θ was 30.2±0.1 degrees in the X-ray diffraction peak.

Comparing an exemplary embodiment with the comparative example, it was seen that the X-ray diffraction peaks of the transparent conductive layers are different in accordance with the deposition temperature of the transparent conductive layer.

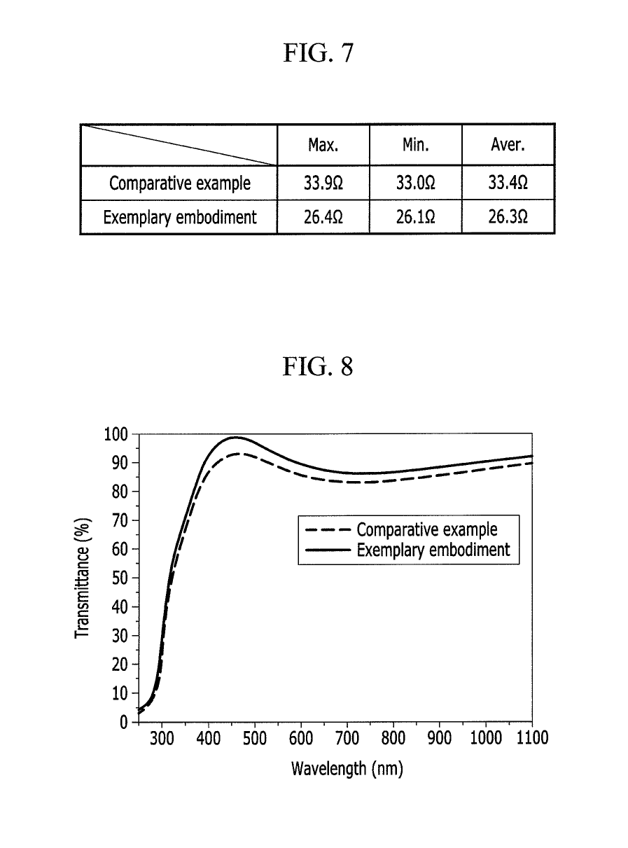

FIG. 7 is a table comparing sheet resistance of the transparent conductive layers of an exemplary embodiment and the comparative example.

In the comparative example, the average of sheet resistance was about 33.4Ω while in an exemplary embodiment, the average of sheet resistance was about 26.3Ω.

That is, it can be seen that the sheet resistance reduces by about 6.9Ω in an exemplary embodiment in comparison to the comparative example.

FIG. 8 is a graph comparing light transmittance of the transparent conductive layers of an exemplary embodiment and the comparative example.

As shown in FIG. 8, it can be seen that the light transmittance increases in an exemplary embodiment in comparison to the comparative example, throughout substantially entire wavelength.

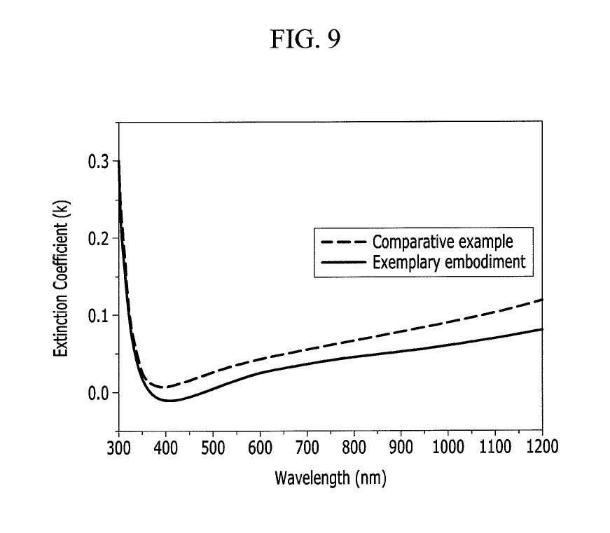

FIG. 9 is a graph comparing light absorptance of the transparent conductive layer of an exemplary embodiment and the comparative example.

As shown in FIG. 9, it can be seen that the light absorptance decreases in an exemplary embodiment in comparison to the comparative example, throughout substantially entire wavelength.

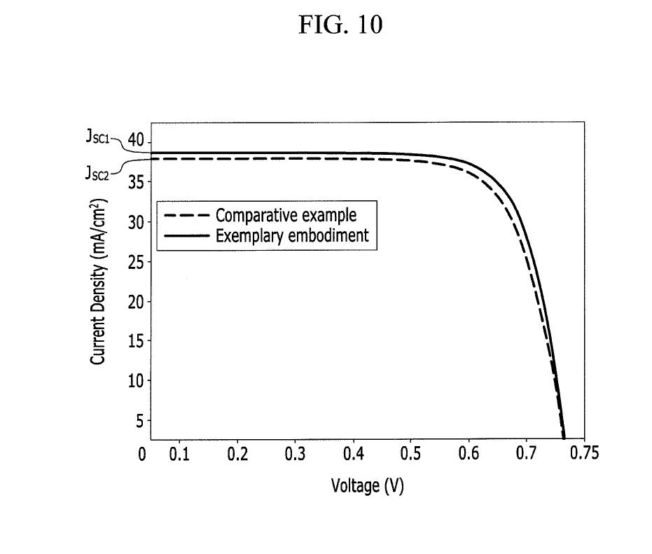

FIG. 10 is a graph comparing characteristics of solar cells according to an exemplary embodiment and the comparative example.

As shown in FIG. 10, it can be seen that the output current Jsc1 of an exemplary embodiment is increased more than the output current Jsc2 of the comparative example. This results from the decrease of light absorptance and the increase of light transmittance in the transparent conductivity layer of an exemplary embodiment, in comparison to the transparent conductive layer of the comparative example.

Further, it can be seen that the fill factor of an exemplary embodiment is increased more than the fill factor of the comparative example. The fill factors are values corresponding to the area of a voltage-current density curve and the larger the fill factor, the more the efficiency of the solar cell increases. The increase in fill factor of an exemplary embodiment is the result of the decrease of sheet resistance of the transparent conductive layer.

In general, the efficiency of the solar cell is proportionate to the output current, fill factor, and voltage and it can be seen that the efficiency is increased in an exemplary embodiment more than the comparative example, comparing an exemplary embodiment with the comparative example. While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for manufacturing a solar cell, comprising:
forming a first semiconductor layer on a first surface of a light-absorbing layer;
forming a second semiconductor layer on a second surface of the light-absorbing layer;
forming a first transparent conductive layer having one X-ray diffraction peak on the first semiconductor layer in a first direction;
forming a second transparent conductive layer having one X-ray diffraction peak on the second semiconductor layer in a second direction opposite to the first direction;
forming a first electrode on the first transparent conductive layer in the first direction; and
forming a second electrode on the second transparent conductive layer in the second direction,
wherein at least one of the first transparent conductive layer and the second transparent conductive layer is formed at about 180 to about 220° C.,
at least one of the first transparent conductive layer and the second transparent conductive layer includes oxidized tungsten, and
2θ is 30.2±0.1 degrees in the X-ray diffraction peak.

2. The method of claim 1, wherein the forming of the first transparent conductive layer or the second transparent conductive layer further includes injecting argon gas and oxygen gas,
wherein the pressure ratio of the argon gas and the oxygen gas is in a range of about 8:1 to about 11:1.

3. The method of claim 2, wherein at least one of the first transparent conductive layer and the second transparent conductive layer further includes oxidized indium.

4. The method of claim 3, wherein a weight ratio of the oxidized indium and the oxidized tungsten in at least one of the first transparent conductive layer and the second transparent conductive layer is about 99:1.

5. The method of claim 3, wherein at least one of the first transparent conductive layer and the second transparent conductive layer further includes at least one of tin (Sn), molybdenum (Mo), titanium (Ti), zirconium (Zr), zinc (Zn), gadolinium (Gd), niobium (Nb), neodymium (Nd) and tantalum (Ta).

6. The method of claim 1, wherein the first transparent conductive layer and the second transparent conductive layer are simultaneously formed.

7. The method of claim 1, wherein sheet resistance of at least one of the first transparent conductive layer and the second transparent conductive layer is in a range of about 26.1 to about 26.4Ω.

8. The method for manufacturing a solar cell of claim 1, wherein the light-absorbing layer is made of crystalline silicon.

9. The method of claim 1, wherein the first semiconductor layer is formed by doping amorphous silicon with P-type impurities.

10. The method of claim 1, wherein the second semiconductor layer is formed by doping amorphous silicon with N-type impurities.

11. A solar cell comprising:
a first semiconductor layer disposed on a first surface of a light-absorbing layer;
a second semiconductor layer disposed on a second surface of the light-absorbing layer;
a first transparent conductive layer disposed on the first semiconductor layer in a first direction;
a second transparent conductive layer disposed on the second semiconductor layer in a second direction opposite to the first direction;
a first electrode disposed on the first transparent conductive layer in the first direction; and
a second electrode disposed on the second transparent conductive layer in the second direction,
wherein at least one of the first transparent conductive layer and the second transparent conductive layer includes oxidized tungsten, and
at least one of the first transparent conductive layer and the second transparent conductive layer has one X-ray diffraction peak, and 2θ is 30.2±0.1 degrees in the X-ray diffraction peak.

12. The solar cell of claim 11, wherein at least one of the first transparent conductive layer and the second transparent conductive layer further includes oxidized indium

13. The solar cell of claim 12, wherein a weight ratio of the oxidized indium and the oxidized tungsten in at least one of the first transparent conductive layer and the second transparent conductive layer is about 99:1.

14. The solar cell of claim 12, wherein at least one of the first transparent conductive layer and the second transparent conductive layer further includes at least one of tin (Sn), molybdenum (Mo), titanium (Ti), zirconium (Zr), zinc (Zn), gadolinium (Gd), niobium (Nb), neodymium (Nd) and tantalum (Ta).

15. The solar cell of claim 11, wherein sheet resistance of at least one of the first transparent conductive layer and the second transparent conductive layer is in a range of about 26.1 to about 26.4Ω.

16. The solar cell of claim 11, wherein the light-absorbing layer is made of crystalline silicon.

17. The solar cell of claim 11, wherein the first semiconductor layer includes amorphous silicon doped with P-type impurities.

18. The solar cell of claim 11, wherein the second semiconductor layer includes amorphous silicon doped with N-type impurities.

19. The method of claim 1, further comprising before forming the first semiconductor layer and the second semiconductor layer, forming a first buffer layer made of amorphous silicon on the first surface of the light -absorbing layer and a second buffer layer made of amorphous silicon on the second surface of the light-absorbing layer.

20. A solar cell comprising:
a first buffer layer formed of amorphous silicon and disposed on a first surface of a light-absorbing layer, wherein the light-absorbing layer is made of crystalline silicon;
a second buffer layer formed of amorphous silicon and disposed on a second surface of the light-absorbing layer;
a first semiconductor layer formed of amorphous silicon doped with P-type impurities and disposed on the first buffer layer in a first direction;
a second semiconductor layer formed of amorphous silicon doped with N-type impurities and disposed on the second buffer layer in a second direction opposite to the first direction;
a first transparent conductive layer disposed on the first semiconductor layer in the first direction ;
a second transparent conductive layer disposed on the second semiconductor layer in the second direction;
a first electrode formed of a low resistance metal and disposed on the first transparent conductive layer in the first direction; and
a second electrode formed of a low resistance metal and disposed on the second transparent conductive layer in the second direction,
wherein each of the first transparent conductive layer and the second transparent conductive layer includes oxidized tungsten and oxidized indium in a weight ratio of the oxidized indium and the ozidized tungsten of about 99:1, and
wherein each of the first transparent conductive layer and the second transparent conductive layer has one X-ray diffraction peak, and 2θ is 30.2±0.1 degrees in the X-ray diffraction peaks of the first transparent conductive layer and the second transparent conductive layer.
